(19) United States
(12) Patent Application Publication
(10) Pub. No.: US 2016/0013433 A1
(43) Pub. Date: Jan. 14, 2016

(54) TRANSPARENT ORGANIC SOLAR CELLS FOR AGRONOMIC APPLICATIONS

(71) Applicant: THE REGENTS OF THE UNIVERSITY OF CALIFORNIA, Oakland, CA (US)

(72) Inventors: Yang Yang, Los Angeles, CA (US); Gang Li, Arcadia, CA (US)

(21) Appl. No.: 14/770,032

(22) PCT Filed: Feb. 25, 2014
(86) PCT No.: PCT/US2014/018388

§ 371 Date: Aug. 24, 2015

Related U.S. Application Data
(60) Provisional application No. 61/768,979, filed on Feb. 25, 2013.

(51) Int. Cl. H01L 51/42; A01G 9/14

(52) U.S. Cl. CPC H01L 51/424; A01G 9/14

(57) ABSTRACT

A greenhouse includes an enclosing structure, with at least a portion of the enclosing structure being at least 10% transparent to sun light in at least a portion of the 400-700 nm range of wavelengths of light. The portion of the enclosing structure that is at least 10% transparent to sun light includes a transparent organic photo-voltaic cell.

### CROSS-REFERENCE OF RELATED APPLICATION

This application claims priority to U.S. Provisional Application No. 61/768,979 filed Feb. 25, 2013, the entire contents of which are hereby incorporated by reference.

### STATEMENT OF GOVERNMENT SUPPORT

This invention was made with Government support under Grant No. N00014-11-1-0250, awarded by the Office of Naval Research. The Government has certain rights in the invention.

### TECHNICAL FIELD

The field of the currently claimed embodiments of this invention relates to transparent organic solar cells. In particular, this invention relates to transparent organic solar cells for use in agronomic applications and structures that incorporate the transparent organic solar cells.

### BACKGROUND

Solar cell technology has been expected to be the most effective method for producing clean energy at low cost and minimum pollution. Beginning from the last century, solar cell technologies have evolved based on various material systems used for harvesting the solar energy. The most traditional and the most commonly available kind of solar cell technology is based on the utilization of crystalline silicon as the active absorbing material. However, due to the high cost of purifying silicon into a high crystalline state, the application of silicon-based solar cells as a major energy source is limited.

In recent years, conductive and semi-conductive conjugated semiconducting polymers or small molecules have attracted much attention for their applications in organic photovoltaics (OPVs) and organic light emitting diodes (OLED). Organic photovoltaics have drawn intense attention due to their advantages over competing solar cell technologies. Current progress in the power-conversion efficiency (PCE) of OPVs has overcome the 10% PCE bather, suggesting a promising future for OPVs as a low-cost and highly efficient photovoltaic (PV) candidate for solar energy harvesting. In addition to the pursuit of high device efficiency, OPVs are also being intensely investigated for their potential in making advances in much broader applications. One of these applications is to achieve high-performance visually transparent or semi-transparent PV devices, which could open up PV applications in many untapped areas such as building-integrated photovoltaics (BIPV). The advantages of OPVs, such as low cost, ease of processing, flexibility, light weight and high transparency make polymer solar cells (PSCs) a good candidate for BIPV purposes.

Visibly transparent OPV (TOPV) devices may provide special advantages in certain situations. Previously, many attempts have been made to demonstrate visually transparent or semi-transparent OPV cells (TOPV or s-TOPV). Transparent conductors, such as thin metal films, metallic grids, metal nanowire networks, metal oxide, conducting polymers, and graphene, have been deposited onto OPV active layers as back electrodes to achieve a solution-processable TOPV or s-TOPV. However, due to the absence of efficient solution processable transparent conductors and effective device architectures, these demonstrations often result in low device performance. Therefore, there remains a need for improved organic electro-optic devices.

### SUMMARY

A greenhouse according to some embodiments of the current invention includes an enclosing structure and at least a portion of the enclosing structure is at least 10% transparent to sun light in at least a portion of the 400-700 nm range of wavelengths of light. The portion of the enclosing structure that is at least 10% transparent to sun light includes a transparent organic photo-voltaic cell.

A panel for a greenhouse according to an embodiment of the current invention includes a transparent organic photo-voltaic cell that is at least 10% transparent to sun light in at least a portion of the 400-700 nm range of wavelengths of light and is responsive to light in a range of wavelengths outside the 400-700 nm range of wavelengths.

### BRIEF DESCRIPTION OF THE DRAWINGS

Further objectives and advantages will become apparent from a consideration of the description, drawings, and examples.

FIG. 1 is a schematic illustration of a greenhouse using transparent photovoltaic cells according to an embodiment of the current invention.

FIG. 2 is a graph of typical absorption spectra for common plant pigments (top) and a graph of typical photosynthetically active radiation (PAR) action spectrum for common plant pigments (bottom).

FIG. 3 is a graph of the transmission spectrum of a typical visibly transparent TOPV device according to an embodiment of the current invention.

FIG. 4 shows examples of some organic photovoltaic materials that can be used according to some embodiments of the current invention.

FIG. 5 shows absorption and action spectrum of photosynthesis in a green algae according to an embodiment of the current invention.

FIG. 6 shows action spectrum of photosynthesis in a red algae according to an embodiment of the current invention.

### DETAILED DESCRIPTION

Some embodiments of the current invention are discussed in detail below. In describing embodiments, specific terminology is employed for the sake of clarity. However, the invention is not intended to be limited to the specific terminology and examples selected. A person skilled in the relevant art will recognize that other equivalent components can be employed and other methods developed without departing from the broad concepts of the current invention. All references cited anywhere in this specification, including the Background and Detailed Description sections, are incorporated by reference as if each had been individually incorporated. All references cited in this specification are incorporated herein by reference.

The term “optically transparent” means that a sufficient amount of light within the wavelength range of operation can pass through for the particular application.

The term “light” is intended to have a broad meaning to include both visible and non-visible regions of the electromagnetic spectrum. For example, infrared and ultraviolet light are intended to be included within the broad definition of the term “light.”

According to embodiments of the current invention, visibly transparent organic photovoltaics (TOPV) solar cells may provide electricity with minimal reduction of solar radiation used by plants, algae, or other biomass to grow. As discussed below, the combination of TOPV with other types of semitransparent solar cells, down conversion materials and/or transparent OLEDs can bring further benefits to these applications. According to some embodiments of the present invention, TOPV has the potential to have wide applications in agricultural greenhouse applications.

According to some embodiments, the term “transparent OPVs” (TOPVs) may include organic solar cells that have an average transparency within the visible light region (about 400 nm-700 nm) (Tₐᵥₑ₋ᵥᵢₛ) of ≧50%. “Semi-transparent OPVs” (s-TOPVs) may include organic solar cells that have Tₐᵥₑ₋ᵥᵢₛ between 0% and 50%. However, as discussed below, TOPVs or s-TOPVs are not limited to these ranges, and certain applications may allow or even require, for example, different amounts of transparency for different wavelengths.

According to embodiments of the current invention, an organic solar cell may be provided that is a visibly transparent OPV (TOPV) with high transparency in the visible region (400-700 nm). Using the solar spectrum, mainly from near-IR (700-900 nm), power conversion efficiency of 5% has been achieved. Thus, high-transparency in certain wavelengths and effective power conversion efficiency may be achieved. This provides a powerful tool for the application of OPV in the field of agriculture.

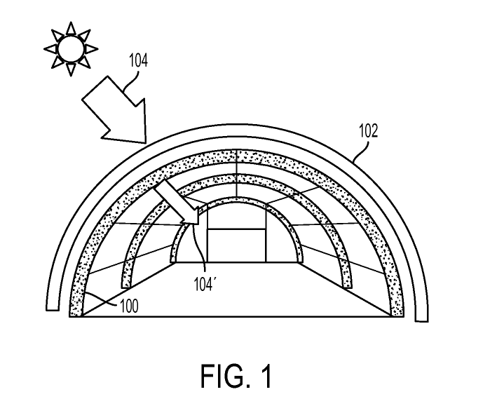

FIG. 1 shows an example of an embodiment of the current invention. FIG. 1 shows a greenhouse structure 100 that incorporates TOPVs 102 on the roof, windows, and/or walls of the greenhouse. The roof, windows, and/or walls of a greenhouse may be made from one or more transparent panes, sheets, and/or films of glass, plastic, or other materials that are known or specially developed. For simplicity, the transparent portions of the greenhouse will herein be referred to as “windows.” Accordingly, “window,” as used herein, is intended to be broadly defined to potentially include any transparent or semi-transparent portion a greenhouse.

The TOPVs 102 can capture some of the radiation 104 from the Sun or other source, while a portion 104′ of the radiation 104 may be allowed to pass through the TOPVs 102 and roof, walls, and/or windows of the greenhouse structure 100. Agricultural plants utilize specialized pigments to intercept and capture radiant energy (portion 104′). For example, plants capture the energy in light during the process of photosynthesis. Within the broad solar light spectrum, the photosynthetically active radiation (PAR) wavelengths (400-700 nm) activate the chlorophyll-A and chlorophyll-B pigments, which transform light energy into chemical energy for production of carbon molecules (sugars) that are then used to construct more complex compounds, and ultimately plant cells and organs (root, leaf, stem, flower, fruit). Accessory pigments include xanthophylls, and carotenoids. Consequently, photovoltaic devices according to some embodiments of the current invention can capture electromagnetic energy in regions of the spectrum that are not used, or used less predominantly, for photosynthesis.

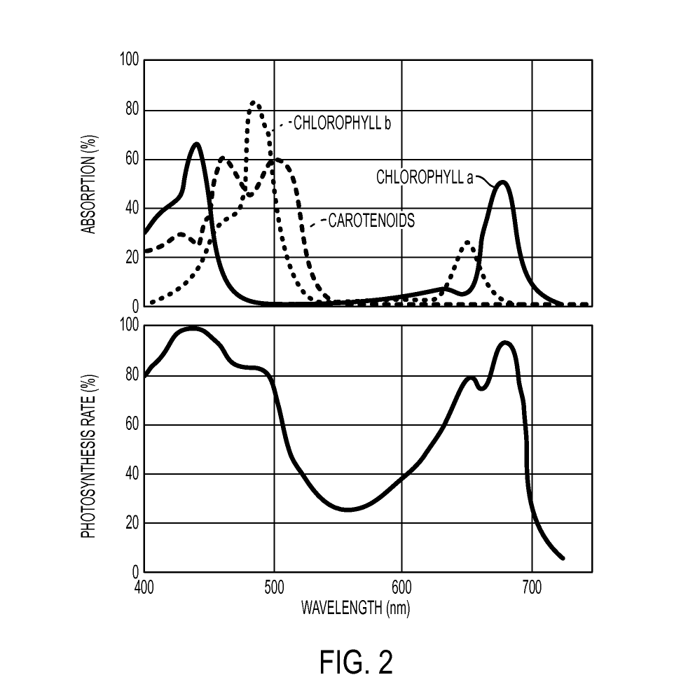

FIG. 2 shows the typical photosynthetically active radiation (PAR) action spectrum, and the absorption spectra for common plant pigments: chlorophyll-A, chlorophyll-B, and carotenoids. For healthy growth of crop plants, high transparency from 400 to 700 nm is therefore important to achieve sufficient light flux and thus more productive agricultural goods.

In addition to providing energy for plant photosynthesis, light also regulates plant growth and development. This is called photomorphogenesis, which involves the activation of several photoreceptor (pigment) systems. For example, plants use primarily blue light for vegetative leaf growth and primarily red light for flowering. Therefore, high transparency in one or more selected spectrum regions within the visible region is also useful in agriculture applications.

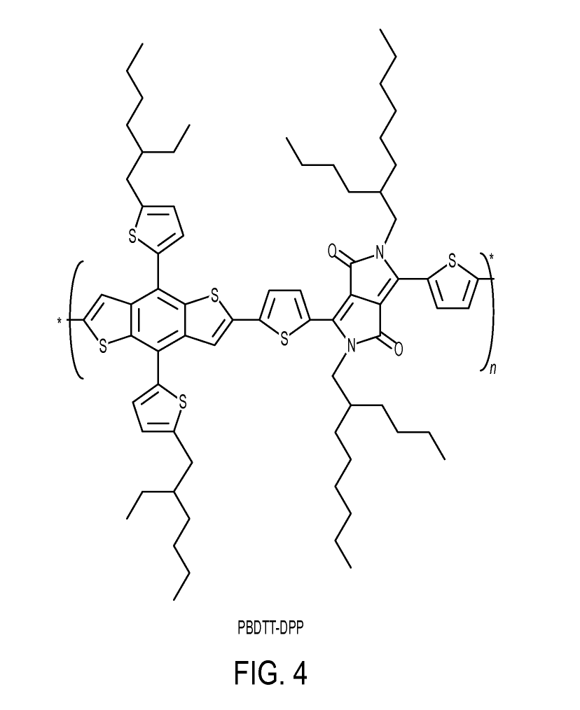

The conventional semitransparent OPV devices use the visible spectrum to convert light into electricity. The transparency of the cell is determined by the thickness of the organic semiconductor layer (and electrode transparency). The light transmission from 400-700 nm is significantly reduced to achieve high power conversion efficiency, and thus more power output. However, the TOPV according to some embodiments of the current invention may use copolymers, such as PBDTT-DPP (see, e.g., L. Dou, Y. Yang et al. Nature Photon. (2012) 6, 180), which is shown in FIG. 4, to absorb mainly in near infrared (NIR) and ultraviolet (UV) regions to convert photon energy to electricity. Therefore, when incorporating transparent electrodes such as silver nanowire (AgNW) or transparent conductive oxide (TCO) electrodes to form the cell/module, it will leave the visible region highly transparent. Therefore, the power generation and light transmission do not need to be compromised.

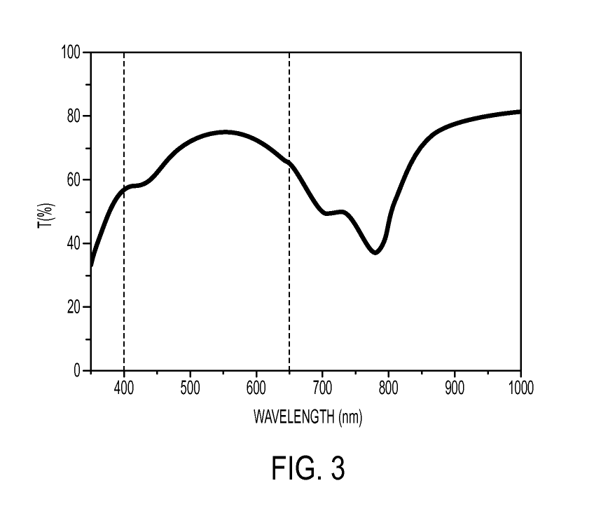

FIG. 3 is the transmission spectrum of a typical visibly transparent OPV cell (TOPV). As seen from FIG. 3, the transmission of the complete device (˜4% PCE) in visible range is above 50%, with the maximum transparency reaching 75%. This indicates that the TOPV itself can provide high, or almost full, transparency in the visible spectrum. In the case where full transparency is not needed across the whole 400-700 nm spectrum, a combination of TOPV with other type of cells can be used to further enhance the power output in agricultural application such as a greenhouse.

Some embodiments of the current invention relate to the following ways of applying OPVs in greenhouse applications.

According to some embodiments, sufficient light in the whole visible spectral region (400-700) may be required. In such applications, visibly transparent OPV (TOPV) may be incorporated into or onto the greenhouse. For example, the greenhouse windows can be made from one or more TOPV modules. Alternatively, one or more TOPV modules can be attached to one or more greenhouse windows.

According to some embodiments, transparency for only part of the visible spectrum may be needed in certain applications. For example, if transparency is only needed or desired for the blue region of the light spectrum (e.g., for vegetative leaf growth within the greenhouse), polymers may be selected which absorb mainly in the longer wavelength section of visible region such as PBT1, which can have absorption up to 800 nm (See YY Liang et al. JACS 2009, 131, 56-57), or small molecules (for example, CuPc and/or ZnPc) may be used to build semi-transparent solar cells (s-TOPV). Such a cell can be used by itself or combined with TOPV for improved power generation.

On the other hand, if transparency is only needed or desired with respect to the red region of the light spectrum (e.g., for flower growth), polymers can be selected which absorb mainly in the shorter wavelength section of visible region. For example, poly(3-hexylthiophene) or P3HT having absorption up to ˜630 nm (see, e.g., G. Li, Y. Yang et al. Nature Mater. 2005, 4, 864), or MEH-PPV/ MDMO PPV having absorption up to ˜570nm (see e.g., Hopp, et al. 2004, 19, 1924) may be used to build a semitransparent solar cell. Further, combining the semitransparent OPV with NIR absorption TOPVs may significantly improve power generation.

According to some embodiments of the current invention, organic dyes, organic light emitting materials, inorganic phosphors, and light emitting quantum dots can also be used as energy down conversion materials (DCMs) to convert short wavelength light to longer wavelength light. A coating of such material(s) can be beneficial in at least the following three cases:
1) The DCM provides emission, typically in the NIR region, that the TOPV can use to generate electricity.
2) The DCM gives long wavelength emission that matches the red spectrum region (e.g., 600-700 nm), thus enhancing the useful irradiation beneficial to the plants.
3) The DCM absorbs UV light and emits blue light, which can be (a) absorbed by TOPV to generated electricity, and/or (b) provided as preferred blue emission for the plants.

FIG. 2 shows that not all of the visible spectrum range is needed for plant growth. Therefore, according to some embodiments, TOPVs can use materials with different (or complementary) absorptions to achieve more efficient electricity generation, while also providing sufficient plant growth conditions. The absorber materials can be, for example, semiconducting polymers, small molecules, oligomers, organic dyes, quantum dots, nano-crystals, etc.

The absorber materials may be incorporated into the TOPVs according to various configurations. According to some embodiments, a multi-material system may be incorporated into a single junction TOPV device/module. For example, a ternary OPV system with two polymers as the p-type absorption material may be used. In some embodiments, a tandem TOPV device/module with different absorbers in each sub-cell may be provided. According to another embodiment, two or more single junction TOPV device/modules with different (or complementary) absorption can be stacked together. In addition to any one of the foregoing embodiments and examples, embodiments of the current invention may include one or more combinations of the above examples.

According to another embodiment of the current invention, an integrated transparent OPV and transparent OLED light source for greenhouse application is provided. Like OPV, OLED can also be made transparent or semi-transparent with selected absorption spectrum. When integrated, the transparent OPV can generate power in the daytime, which may then be stored it in a battery, for example. The battery may then be used to drive the OLED lighting in the night time.

According to some embodiments, the whole visible solar spectrum may need to only be semitransparent. In such applications, a larger portion of solar spectrum may be used for power generation. For example, for the visible region, visibly response OPV materials (such as benzodithiophene (BDT)-Thienothiophene (TT) series copolymers) may be used for semitransparent solar cells to collect the visible range, and visibly transparent OPV (TOPV) to collect near IR solar energy. This may lead to significantly improved solar energy conversion efficiency. Alternatively, a combination of semitransparent dye-sensitized solar cells (DSSC) can combine with TOPV for the same purpose.

The following provides some examples according to some embodiments of the current invention. The general concepts of the current invention are not limited to these particular examples that are provided to explain concepts of the current invention.

### EXAMPLES

Embodiments of the current invention have applications for a wide variety of plants and biological organisms and for various uses. For example, solar fuel through biomass is believed to be one of the major future renewable energy sources. Biodiesel generation using microalgae is so far the most efficient way of convert solar energy to fuel, with the peak algae performance being equivalent to 4% average sunlight energy converted to biodiesel according to the National Renewable Energy Laboratory (NREL).

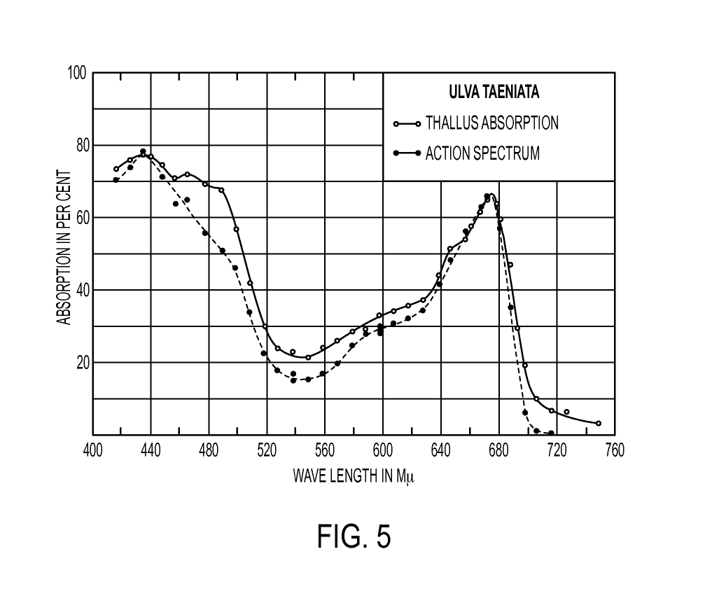

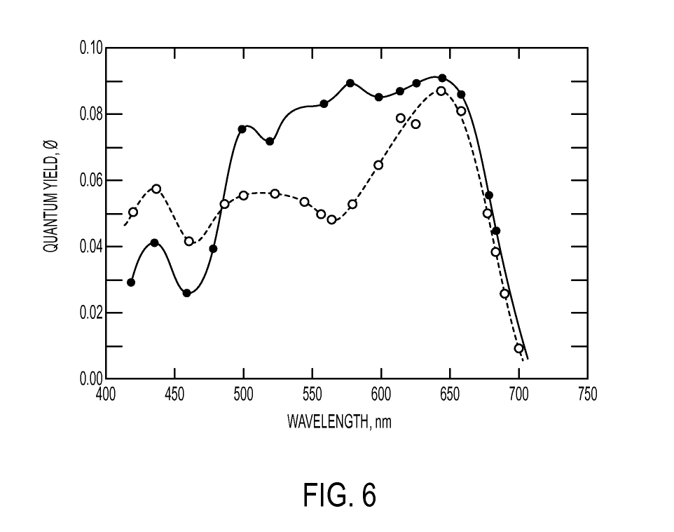

In converting solar irradiation to biomass, however, algae only need to use a limited section of solar spectrum, similar to the plants discussed above. FIG. 5 shows the absorption and action spectrum of photosynthesis in a green algae—ULVA TAENIATA, and FIG. 6 shows action spectrum of photosynthesis in a red algae. As shown in FIGS. 5 and 6, the algae mostly needs only the light below ˜700 nm. Therefore, only the visible range of the solar spectrum is needed by the algae for conversion.

The TOPVs according to some of the above-described embodiments for plant/agriculture applications may be used to realize higher solar energy conversion via the integration of algae-based solar fuel system and TOPV-based solar photovoltaic system. Similarly, biomass/fuel systems may be provided that use cyano bacteria, for example, or other bacteria. The TOPV unit will mainly use the solar radiation that is not crucial to biomass growth. For example, the algae/cyano-bacteria based solar fuel unit will mainly use radiation in the range of 400-700 nm.

For some applications, there may be certain sections of the visible light spectrum that are not efficient in fuel generation for that application. For example, the 500-640 nm section when using green algae (see FIG. 5). Therefore, the solar cell spectrum response can be tuned to also use that section of light to maximize the total solar energy conversion efficiency.

There is also a clear difference in “optimal” light intensity for biomass vs. crop growth. While crops typically prefer high light intensity (e.g., a full sun), micro algae requires much lower intensity light. For example, it is found that the multiplication rate of algal cells was highest at ˜27-31° C. , with photon flux of 100 μmol m⁻²s⁻¹, while the one-sun condition is equivalent to ˜2000 μmol m⁻²s⁻¹, or about 20 times the light that algal biomass needs. Therefore, for the growth of some organisms, a TOPV may need to be at least 50% transparent to light of at least a portion of the wavelength used by that organism. However, for other organisms (e.g., algae), may need to only be at least 10% transparent to light of at least a portion of the wavelength used by that other organism. This means there can be more sunlight for solar electricity generation, with no negative effect on algal biomass production. Therefore there are multiple ways to achieve high efficiency for the integrated solar PV/fuel system, including increasing active layer absorption including via donor or acceptor molecules, reducing the transparency of the electrode, etc.

In summary, visibly transparent OPV (TOPV) can have wide application for agricultural greenhouses. The solar cells can provide electricity with minimal reduction of solar radiation for plants to grow. A combination of TOPV with other types of semitransparent solar cells, down conversion materials and/or transparent OLEDs can provide additional benefits.

Some concepts of the current invention were described with particular examples. The general concepts of the current invention are limited to the particular examples.

### REFERENCES

1. Letian Dou, Jingbi You, Jun Yang, Chun-Chao Chen, Youjun He, Seiichiro Murase, Tom Moriarty, Keith Emery, Gang Li and Yang Yang, “Tandem polymer solar cells featuring a spectrally matched low-bandgap polymer,” Nature Photonics 6, 180-185 (2012).

2. Gang Li, Vishal Shrotriya, Jinsong Huang, Yan Yao, Tommoriarty, Keith Emery and Yang Yang, “High-efficiency solution processable polymer photovoltaic cells by self-organization of polymer blends,” Nature Materials, 4, 864-868 (2005).

3. Hopp, et al. 2004, 19, 1924

4. Jianhui Hou, Hsiang-Yu Chen, Shaoqing Zhang, Ruby I. Chen, Yang Yang, Yue Wu and Gang Li, “Synthesis of a Low Band Gap Polymer and Its Application in Highly Efficient Polymer Solar Cells,” Journal of American Chemical Society, 131 (43), 15586-15587 (2009)

5. “A review of effect of light on microalgae growth”, Maryam Al-Qasmi, Nitin Raut, Sahar Talebi, Sara Al-Rajhi, Tahir Al-Barwani. Proceedings of the World Congress on Engineering 2012 Vol I. WCE 2012, Jul. 4-6, 2012, London UK. ISBN:987-988-19251-3-8, ISSN:2078-0966 (Online)

6. “Conversion—PPF to Lux,” Apogee Instruments, http://www.apogeeinstruments.com/conversion-ppf-to-lux/

We claim:

1. A greenhouse comprising an enclosing structure, wherein at least a portion of the enclosing structure is at least 10% transparent to sun light in at least a portion of the 400-700 nm range of wavelengths of light, and
wherein at least a portion of the enclosing structure that is at least 10% transparent to sun light comprises a transparent organic photo-voltaic cell.

2. The greenhouse according to claim 1, wherein said transparent organic photo-voltaic cell is at least 10% transparent to sun light in at least a portion of the 400-700 nm range of wavelengths of light and is responsive to light in a range of wavelengths outside said 400-700 nm range of wavelengths.

3. The greenhouse according to claim 2, wherein said transparent organic photo-voltaic cell is responsive to light in at least a portion of the 700-900 nm range of wavelengths of light.

4. The greenhouse according to claim 1, wherein said transparent organic photo-voltaic cell is at least 10% transparent to sun light in at least a portion of the 400-550 nm range of wavelengths of light and at least a portion of the 620-700 nm range of wavelengths of light.

5. The greenhouse according to claim 1, wherein at least a portion of the enclosing structure is less than 10% transparent to sun light in at least a portion of the 400-700 nm range of wavelengths of light,
wherein at least a portion of the enclosing structure that is less than 10% transparent to sun light comprises a photo-voltaic cell.

6. The greenhouse according to claim 1, wherein the at least a portion of the enclosing structure is at least 10% transparent to sun light in at least a portion of the range of wavelengths of light above 630 nm.

7. The greenhouse according to claim 1, wherein the at least a portion of the enclosing structure is at least 10% transparent to sun light in at least a portion of the range of wavelengths of light above 570 nm.

8. The greenhouse according to claim 1, further comprising a down converter material on a surface of the enclosing structure,
wherein said down converter material converts shorter wavelength light to longer wavelength light.

9. The greenhouse according to claim 8, wherein said longer wavelength light is in at least a portion of the range of wavelengths of light between 400-700 nm.

10. The greenhouse according to claim 4, wherein said transparent organic photo-voltaic cell is at least 10% transparent to sun light in at least a portion of the 400-500 nm range of wavelengths of light and at least a portion of the 640-700 nm range of wavelengths of light.

11. The greenhouse according to claim 1, wherein the at least a portion of the enclosing structure that is at least 10% transparent to sun light in at least a portion of the 400-700 nm range of wavelengths of light is at least 50% transparent to sun light in at least a portion of the 400-700 nm range of wavelengths of light.

12. A panel for a greenhouse, comprising a transparent organic photo-voltaic cell that is at least 10% transparent to sun light in at least a portion of the 400-700 nm range of wavelengths of light and is responsive to light in a range of wavelengths outside said 400-700 nm range of wavelengths.

13. A method of producing energy from solar radiation, comprising:
providing a greenhouse that has photovoltaic cells on at least a portion of an enclosing structure thereof; and
disposing fuel-producing algae within said greenhouse,
wherein said photovoltaic cells are at least 10% transparent to sun light within at least a portion of the wavelength range of 400-700 nm, and
wherein said photovoltaic cells absorb sufficient amounts of sun light outside said wavelength range of 400-700 nm to generate electrical energy.

14. The method of claim 13, wherein said photovoltaic cells absorb sufficient amounts of sun light in at least a portion of the wavelength range of 700-900 nm to generate electricity.

15. The method of claim 13, wherein said photovoltaic cells are at least 10% transparent to sun light within at least a portion of the wavelength range of 400-550 nm and at least a portion of the wavelength range of 620-700 nm.

16. The method of claim 13, further comprising:
providing at least one down converter material on said greenhouse,
wherein said at least one down converter material converts shorter wavelength light to longer wavelength light.
